(19) United States
(12) Patent Application Publication
(10) Pub. No.: US 2008/0236873 A1
(43) Pub. Date: Oct. 2, 2008

(54) ELECTRONIC COMPONENT AND METHOD FOR MANUFACTURING THE SAME

(75) Inventor: Hajime Kuwajima, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK CORPORATION, Tokyo (JP)

(21) Appl. No.: 12/029,756

(22) Filed: Feb. 12, 2008

(30) Foreign Application Priority Data
Mar. 29, 2007 (JP) 2007-089899

(51) Int. Cl. H05K 1/09; H05K 3/00

(52) U.S. Cl. 174/257; 29/842

(57) ABSTRACT

An electronic component is: formed by laminating multiple conductive films and multiple insulating films; and provided with an extraction electrode which is extracted to be exposed from the insulating films for establishing connection to another electrode. The electronic component includes a shield film configured to cover an interface between the extraction electrode and the insulating film that covers the internal conductor. The shield film is either an inorganic film or a conductive film having resistance to a degreasing agent, a plating solution, a solvent, an etching solution, a surface activating solution, and the like, as well as moisture resistance, etching resistance, gas permeation resistance, and corrosion resistance.

### BACKGROUND OF THE INVENTION

The present invention relates to an electronic component and a method for manufacturing the same. More specifically, the present invention relates to a technique for improving reliability of an electronic component by enhancing durability of a joint between an internal conductor and an external connection terminal.

Chip electronic components (hereinafter also simply referred to as chips in some cases) including various discrete components such as chip capacitors, chip inductors or chip resistors, and various electronic devices formed by combining multiple active and passive elements are offered today. In general, these electronic components have a lamination structure in which conductive films made of conductive materials and insulating films made of insulative materials are laminated. In addition, these electronic components generally include various functional element units corresponding to the types of the chips. Such functional element units include capacitor electrodes, inductor conductors, resistor conductors, and lines for impedance adjustment. Moreover, these functional element units are covered with insulating films and protective films in order to prevent short circuits, disconnection, deterioration and corrosion inside the chips, and in order to protect the chips against processing liquids used in chip manufacturing steps or against physical external forces, damages, moisture, and so forth that the chips receive after the chips are mounted in products.

Meanwhile, these chips include terminal electrodes for external connection provided on outer surfaces due to necessities to establish electrical and mechanical contacts with external devices (such as mounting boards). To connect the terminal electrode to the functional element unit inside the chip, the internal conductor electrically connected to the functional unit may be extracted so as to be exposed from the insulating film and the protective film, and the terminal electrode may be formed so as to be bonded to the electrodes thus extracted (extraction electrodes). Moreover, these extraction electrodes are used not only for connecting the terminal electrodes to the internal conductors but also for connecting the internal conductors between upper and lower wiring layers that are vertically arranged inside the chip, for example.

FIG. 5 is a cross-sectional view schematically showing a terminal electrode in a conventional electronic component. As shown in the drawing, the conventional electronic component is formed by sequentially stacking a planarization film 2, a lower conductor 3, a dielectric film 4, an insulating film 5, an upper conductor 6, a protective film 7, and so forth on a surface of a base substrate 1 that constitutes a core. To connect internal conductors to a terminal electrode 10, the internal conductors (the upper conductor and the lower conductor in this example) are exposed from the protective film 7 as well as the insulating film 5 on an end of the base substrate 1, and then the terminal electrode 10 is formed on a side surface 1a of the base substrate 1 so as to be electrically connected to the exposed section.

The terminal electrode 10 can be formed by sequentially depositing a Cr film 11a and a Cu film 11b collectively as a foundation film 11 by sputtering, then depositing a Cu film 12 constituting a main layer of the electrode, a Ni film 13 serving as a barrier layer, and a Sn film 14 for enhancing solder wettability sequentially thereon by barrel plating, for example. Meanwhile, the upper conductor 6 and the lower conductor 3 can be formed by sequentially depositing a Ti film and a Cu film by sputtering and then depositing a Cu film thereon by electrolytic plating, for example.

Here, the upper conductor 6 and the lower conductor 3 constitute extracted sections of the internal conductors that belong to different wiring layers vertically laminated inside the chip with the insulating film 5 interposed therebetween. In the drawing, only the extracted section (a joint of the two conductors) is illustrated. Moreover, this example applies a structure configured to connect the upper conductor 6 and the lower conductor 3 to each other at an end of the chip, and further to connect these conductors to the terminal electrode 10. In this respect, it is possible to provide only one of these conductors (only one of the upper conductor 6 and the lower conductor 3 in the drawing). Alternatively, it is also possible to provide three or more conductors (a structure in which another conductor is connected thereto, i.e. a structure in which the internal conductors on three or more wiring layers are connected to one another).

Japanese Unexamined Patent Application Publication No. Heisei 9(1997)-270342 discloses the above-described electrode structure.

### SUMMARY OF THE INVENTION

Defects of joints between electrodes such as internal conductors and terminal electrodes are sometimes observed in conventional electronic components. In this context, there is room for further improvement to enhance reliability of electronic components.

To be more precise, when a terminal is observed before and after processes for forming a foundation layer of a terminal electrode, for example, after execution of chemical cleaning such as a degreasing process, the followings are found out. Specifically, in some cases, the protective film 7 is detached from the electrodes 6 and 10, whereby the electrodes 6 and 10 are eroded and corroded, or residues exist on interfaces between the protective film 7 and the electrodes 6 and 10. Such phenomena are observed after cleaning as a pre-process of barrel plating for forming the main layer 12 as well as the surface layers 13 and 14 of the terminal electrode 10. Alternatively, such phenomena are also observed after flux cleaning for soldering the finished chip. When the electronic components are mounted on various devices and used for a long time period as products, the interface detachment, erosion, corrosion, residues, and other phenomena may deteriorate the characteristics of the devices, and cause decrease in durability.

Moreover, deterioration in quality such as IR deterioration or capacitor open/short faults are sometimes observed in reliability evaluation tests including a moisture exposure test, a high-moisture load test, and a water absorption reflow test. Variation in the limit value is also observed in a withstand voltage test.

In addition to the deterioration attributable to the chemical loads as described above, there is also a risk of defects caused by physical and mechanical loads in a chip processing step. To be more precise, from the viewpoint of mass productivity, the above-described electronic component is typically manufactured by: depositing and laminating the respective films on a single base member (in a state of aggregating numerous chips) to collectively form the internal conductors (functional elements); and cutting this base member into the individual chips. In this respect, in some cases, cutting burrs are generated or the interface detachment is caused due to the damaged films, in the process to divide the base member into the individual chips. Moreover, internal stress may be inherent in the respective films as a consequence of deposition and lamination, and this latent internal stress may be released at the time of division into the individual chips. This internal stress may also lead to detachment of the films inside the respective chips.

In the meantime, it is also conceivable to form the respective films to avoid cutting positions by allowing the respective laminated films 3, 6, and 7 to retract from a cutting point (a base substrate side surface 1a) instead of forming the respective films in the aggregate state collectively as continuous films as shown in FIG. 6. Although this structure can also avoid physical damages on the films at the time of the cutting process, the interface between the protective film 7 and the upper conductor 6 remains exposed. Accordingly, a problem similar to the above-described conventional structure (FIG. 5) may occur as a result of another process using a chemical solution or during the use after mounting.

Therefore, it is an object of the present invention to enhance durability of a joint of an internal conductor and another electrode and to further improve reliability of an electronic component.

To attain the object, an electronic component according to the present invention is an electronic component formed by laminating a conductive film and an insulating film and provided with an extraction electrode which is extracted to be exposed from the insulating film for establishing connection to another electrode. Here, the electronic component includes a shield film configured to cover an interface between the extraction electrode and the insulating film covering the internal conductor.

The shield film is preferably made of a material having one or both of chemical resistance, namely, resistance to at least any of a surface activating solution including a degreasing agent, an acidic chemical solution and an alkaline chemical solution, and resistance to any of a plating solution and an etching solution. Moreover, the shield film is preferably made of the material having moisture resistance, gas permeation resistance, and corrosion resistance. Particularly, in terms of material properties, the shield film in the present invention is required to have resistance to various chemicals and solvents applied after the presence of the interface between the internal conductor and the insulating film.

To be more precise, the shield film can be formed as an inorganic film. For example, the shield film may be a film containing any of SiO₂, SiN, Al₂O₃, TaO, CaO, MgO, TiO, and TiN as a main component.

Instead, the shield film can be formed as a conductive film. For example, the shield film may be a film containing any of Cr, Ni, Ti, Cu, W, Ag, and Al as a main component. By forming the shield film as the conductive film, it is possible to establish electrical connection to another electrode even if the entire extraction electrode inclusive of the interface (a boundary) with the insulating film is covered with the shield film. Meanwhile, in the case of forming the shield film as the inorganic film as described above, it is possible to ensure the electrical connection to another electrode by forming the shield film so as not to cover part of the extraction electrode other than the boundary with the insulating film.

Moreover, it is possible to obtain a favorable shielding characteristic when the conductive film constituting the shield film is formed into a thin film by sputtering. It is to be noted, however, that the shield film can also be formed by other vapor deposition methods (such as a vapor deposition or a CVD method) or by electroless plating, for example.

The extraction electrode is provided on an end of a surface of the electronic component while the other electrode to be connected thereto is typically a terminal electrode that is provided on a side surface of the electronic component. Here, the “surface” of the electronic component stated herein does not only mean an upper surface (a top surface) but also includes a lower surface (a bottom surface) as well as an internal surface (an inner layer) of the chip. The extraction electrode may be located on any one of the upper surface and the lower surface, or may be provided on both of the upper surface and the lower surface. Meanwhile, the “side surface” includes all peripheral surfaces of the chip, namely, end surfaces on both ends in a longitudinal direction and end surfaces on both ends in a lateral direction on the assumption that the chip has a hexahedronal (either cubic or rectangular parallelepiped) shape. If the chip has any other three-dimensional shapes such as a triangle, a polygon such as a pentagon or a higher order, a circle or an ellipse from a plan view, then the side surface includes all outer peripheral surfaces of the chip connecting the top surface and the bottom surface thereof.

Further, the “other electrode” does not only mean the terminal electrode provided on the chip side surface but also includes various electrodes provided on the surface or inner layers of the chip. Meanwhile, the shield film may also be configured to cover not only the interface between the extraction electrode and the insulating film but also the entire extraction electrode, or moreover, part or all of the insulating film together with the interface. Furthermore, the “insulating film” encompasses not only the insulating film to be provided for establishing electrical insulation among the various conductors included in the electronic component but also a broad range of insulating films including a dielectric film provided for forming a capacitor, a protective film formed on the outermost layer of the chip for protecting the electronic component, a planarization film formed for smoothing the surface, and a substrate, which are connected to the extraction electrode.

The extraction electrode may be formed so as to retract a tip end thereof inward from the side surface of the electronic component. By retracting the extraction electrode as described above, it is possible to reduce or prevent mechanical and physical loads on the films associated with a cutting process of the chips in the same way as that of the above-described example of improvement shown in FIG. 6.

According to the electronic component of the present invention, the interface (the boundary) between the extracted section (the extraction electrode) of the internal conductor extracted so as to be exposed from the insulating film to establish connection to the other electrode and the insulating film is covered with the shield film. Therefore, it is possible to block intrusion of various chemicals that are used in the manufacturing process of the chip into a space between the extraction electrode and the insulating film, and to prevent intrusion of moisture after the electronic component is mounted on a product. Moreover, assume that an external force is applied to the base member in the aggregate state including the chips or to the chip formed into the individual device, or that the latent internal stress is applied to the interface between the extraction electrode and the insulating film. Even in this case, the shield film is able to: bear these loads; suppress detachment of the films; and thus protect the interface.

A method for manufacturing an electronic component according to the present invention is a method for manufacturing an electronic component by simultaneously forming multiple electronic components, each of which includes an internal conductor covered with an insulating film and an extraction electrode formed so as to extract and expose this internal conductor from the insulating film for establishing connection to another electrode, in an aggregate state on a single base member and then forming the electronic components individually by cutting the base member into chips. Here, the method includes a shield film forming step of providing each of the electronic components on the base member with a shield film covering an interface between the extraction electrode and the insulating film.

In a dicing (cutting) process for dividing the base member into the chips, the stress is applied to the respective films (the conductor films and the insulating films) laminated in the base member. Nevertheless, in the case of such stress application, the interface between the extraction electrode and the insulating film is hardly detached because the shield film is provided so as to cover the interface between the extraction electrode and the insulating film. Even if the case of detachment on the interface, it is still possible to prevent intrusion of the processing solutions (such as a degreasing solution or a plating solution) in the subsequent processes from the interface into the inner layers of the chip as the interface is covered with the continuous shield film.

According to the present invention, it is possible to enhance durability of a joint between an internal conductor and another electrode and thereby to further improve reliability of an electronic component.

Other objects, features and advantages of the invention will become apparent from the following description of the embodiments of the invention taken in conjunction with the accompanying drawings. In the drawings, similar reference characters denote similar elements throughout the several views.

### BRIEF DESCRIPTION OF THE DRAWINGS

FIG. 1 is a view schematically showing a cross-sectional structure of a terminal electrode in an electronic component according to a first embodiment of the present invention.

FIG. 2 is a cross-sectional view showing a state before forming the electronic components according to the first embodiment into chips (an aggregate state before dicing).

FIG. 3 is a view schematically showing a cross-sectional structure of a terminal electrode in an electronic component according to a second embodiment of the present invention.

FIG. 4 is a view schematically showing a cross-sectional structure of a terminal electrode in an electronic component according to a third embodiment of the present invention.

FIG. 5 is a view schematically showing a cross-sectional structure of a terminal electrode in a conventional electronic component.

FIG. 6 is a view schematically showing an improved cross-sectional structure of the conventional terminal electrode.

### DESCRIPTION OF THE EMBODIMENTS

### First Embodiment

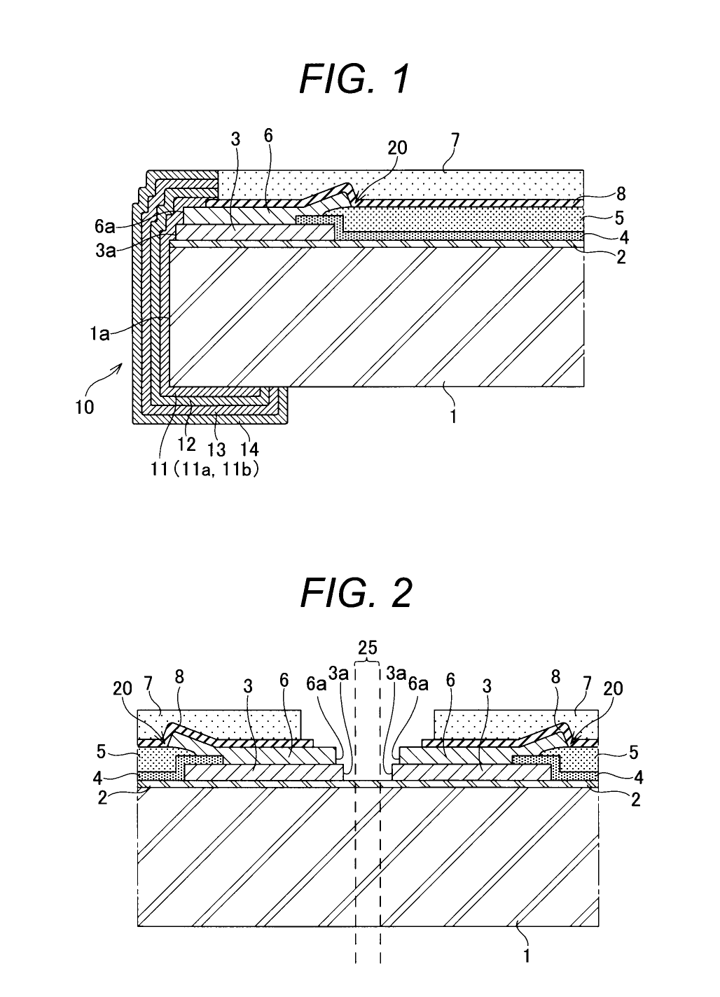

FIG. 1 is a cross-sectional view schematically showing a terminal electrode of an electronic component according to a first embodiment of the present invention. As shown in the drawing, an electronic component (a chip) of this embodiment includes a planarization film 2 formed on a surface of a base substrate 1 constituting a core, multiple conductive films 3 and 6 (wiring layers) laminated thereon, an insulating film 5 (including a dielectric film 4 and constituting an insulating layer) interposed between the conductor films for insulating these films, and a terminal electrode 10 provided on a side surface 1a of the base substrate 1. Moreover, a protective film 7 is formed on the outermost surface of the chip.

Here, FIG. 1 shows a structure for electrically connecting the two conductive films 3 and 6 (inner conductors) to each other and for electrically connecting these conductive films 3 and 6 to the terminal electrode 10. Moreover, of the illustrated conductive films 3 and 6, the extraction electrode 3 located on a lower side and the extraction electrode 6 located on an upper side are extracted sections of the internal conductors that belong to mutually different wiring layers, which are vertically laminated in the chip with the insulating film 5 interposed therebetween. The drawing shows only the extracted sections (joints of these conductors).

Meanwhile, this example applies the structure configured to connect these internal conductors to each other at the end of the chip, and to connect these conductors to the terminal electrode 10. In this respect, it is possible to provide only one internal conductor (only one of the extraction electrode 3 on the lower side and the extraction electrode 6 on the upper side in the drawing). Alternatively, it is also possible to provide three or more conductors (a structure in which another extraction electrode extracted from a different internal conductor is connected thereto, i.e. a structure in which the internal conductors on three or more wiring layers are connected to one another). Further, it is also possible to apply a structure configured to simply connect multiple internal conductors to one another regardless of the terminal electrode 10 (without connection to the terminal electrode 10). The same applies to other embodiments to be described later.

In this embodiment, the lower conductive film inclusive of the lower extraction electrode 3 is formed on the surface of the base substrate 1 smoothed by use of the planarization film 2 as described above, and the dielectric film 4 and the insulating film 5 are formed thereon. Thereafter, the upper conductive film inclusive of the upper extraction electrode 6 is formed on the insulating film 5. Here, the upper extraction electrode 6 is formed so as to be exposed at the end of the base substrate 1, and superposed on the lower extraction electrode 3 that is similarly formed to be exposed at the end of the base substrate 1. In this way, the lower extraction electrode 3 is electrically connected to the upper extraction electrode 6. Note that it is possible to provide only one of the dielectric film and the insulating film on the lower conductive film and on the upper conductive film. Alternatively, it is also possible to laminate multiple insulating films or multiple dielectric films (the same applies to other embodiments to be described later).

The planarization film 2 is can be formed by use of A1203, for example. Meanwhile, the lower conductive film 3 and the upper conductive film 6 can be respectively formed by: sequentially depositing a Ti film and Cu film in accordance with a sputtering method, for example; and then depositing a Cu film by means of electrolytic plating while using the Ti film and the Cu film as foundation films. Meanwhile, the dielectric film 4, the insulating film 5 and the protective film 7 can be formed by use of resin (such as polyimide, epoxy resin, benzocyclobutene (BCB) or fluororesin) or inorganic materials (such as SiN, SiO₂, Al₂O₃ or TaO).

After formation of the upper conductive film (and the upper extraction electrode 6), a shield film 8 is formed on upper surfaces of the upper extraction electrode 6 and of the insulating film 5 so as to cover an interface 20 between the upper extraction electrode 6 and the insulating film 5. This shield film is made of an inorganic material containing any of SiO₂, SiN, Al₂O₃, and TaO as a main component so as to achieve high chemical resistance and high adhesion to the conductive film 6 as well as the insulating film 5. Moreover, this shield film 8 is not formed on a tip end of the extraction electrode 6 so that the tip end of the extraction electrode 6 remains exposed from the shield film 8, in order to establish electrical connection to the terminal electrode 10 to be formed on a side surface of the chip.

Moreover, tips 3a and 6a of the respective extraction electrodes 3 and 6 are formed so as to be retracted inward (toward the center of the chip) from the side surface la of the base substrate 1, in order to protect the extraction electrodes 3 and 6 against physical and mechanical loads generated at the time of forming the chips (a cutting process). Specifically, FIG. 2 shows a manufacturing process for the chip of this embodiment (a state before dicing). As shown in this drawing, the chip in this embodiment (and similarly in other embodiments) is formed by: forming the respective films on the base substrate 1 in an aggregate state; and then cutting the base substrate 1 as shown in dashed lines 25 in the drawing after collectively forming multiple chips so as to divide base substrate 1 into individual chips. Therefore, the extraction electrodes (the lower conductive film and the upper conductive film) 3 and 6 are formed to avoid the cutting lines 25 so that an external force is not applied to these extraction electrodes (the conductive films) 3 and 6 in the cutting process. Here, sectional surfaces obtained in this process constitute the side surfaces 1a of the chips.

The protective film 7 is further formed on the shield film 8, and then the terminal electrode 10 is provided on the side surface of the chip. This terminal electrode 10 is formed by: sequentially depositing a Cr film 11a and a Cu film 11b collectively as a foundation film 11 by sputtering; depositing a Cu film 12 constituting a main layer of the electrode 10 by barrel plating; and then depositing a Ni film 13 serving as a barrier layer and a Sn film 14 for enhancing solder wettability sequentially thereon, for example.

The above-described protective film 7 is also provided frequently on the outermost layer of a chip in a conventional case as similar to this embodiment. In this respect, the protective film of this type, which has heretofore been provided, is able to protect electrodes and functional films serving as wiring and the like of the chip physically and mechanically. However, the protective film of this type is not able to completely shield moisture or various processing liquids on an interface between an extraction electrode and an insulating film such as the protective film. As a consequence, the conventional countermeasures have been limited to lamination of multiple protective film layers or provision of a package by resin molding. Such countermeasures cause an increase in the overall size and thickness of products as well as an increase in manufacturing costs of electronic components. On the contrary, according to this embodiment, the interface 20 between the extraction electrode 6 and the insulating film 5 is covered with the shield film 8 regardless of the presence of the protective film 7. Therefore, it is possible to prevent intrusion of moisture and the like from the interface 20 and corrosion and deterioration of the internal conductors more reliably than the conventional technique.

### Second Embodiment

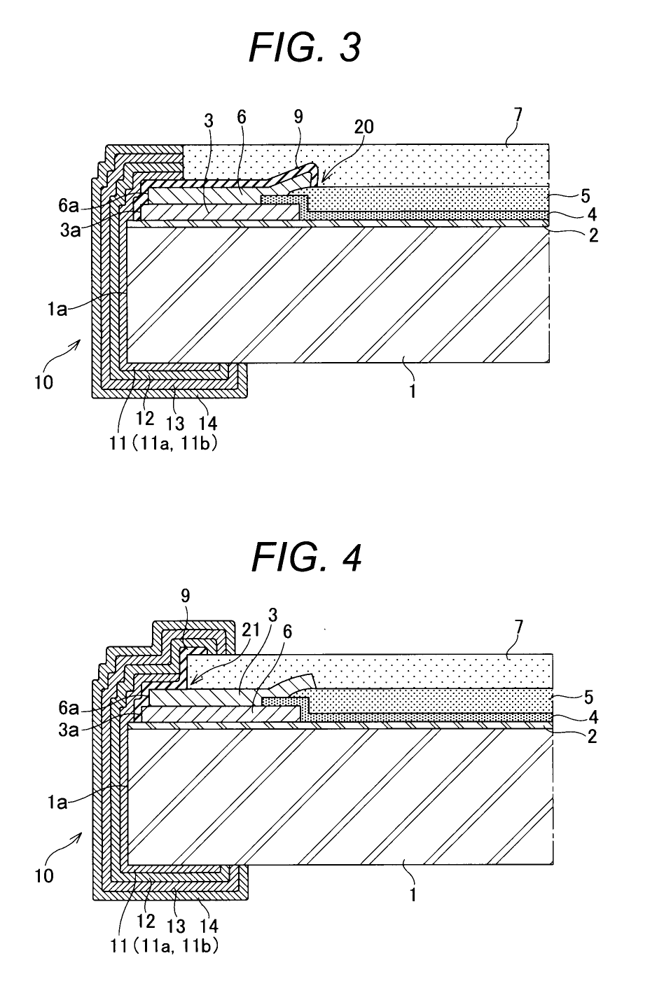

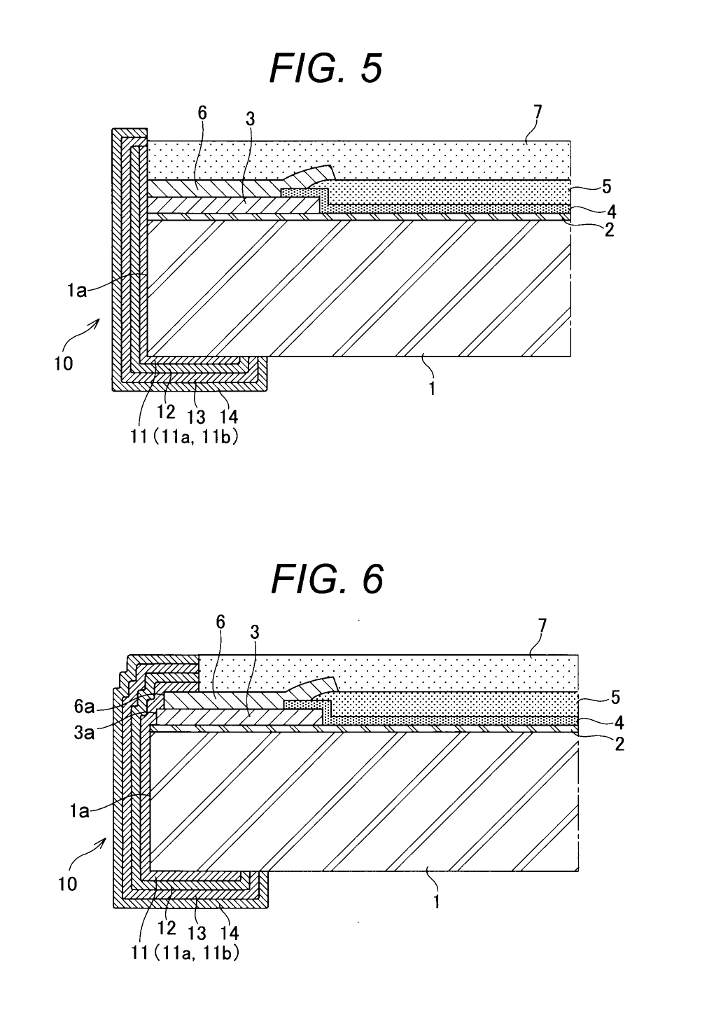

FIG. 3 is a cross-sectional view schematically showing a terminal electrode in an electronic component according to a second embodiment of the present invention. As shown in the drawing, an electronic component (a chip) of this embodiment includes the planarization film 2, the lower conductive film (the lower extraction electrode) 3, the dielectric film 4, the insulating film 5, the upper conductive film (the upper extraction electrode) 6, a shield film 9, and the protective film 7 which are sequentially formed on the surface of the base substrate 1, and the terminal electrode 10 provided on the side surface 1a of the base substrate 1 as similar to the first embodiment. Here, the shield film 9 is formed as a conductive film.

To be more precise, the shield film 9 is formed as a sputtered film made of a material containing any of Cr, Ni, Ti, Ni—Cr alloy, Cu, Ag, Al, and W alloy. Here, it is also possible to form the shield film 9 by laminating multiple layers using these metal substances. In this case, it is favorable to form a dense conductive film having small grains (such as grain sizes equal to or below 1.0 μm, more preferably equal to or below 0.5 μm, or even more preferably equal to or below 0.1 μm) by means of reducing a film deposition rate, for example, in light of enhancement in a shielding property, adhesion, and a tracking property of the shield film 9 relative to steps (irregularities on boundaries between the extraction electrodes 3 and 6 or between these extraction electrodes with the insulating film 5). In addition to the sputtering method, the shield film 9 can also be formed by other gas-phase film deposition methods such as a vapor deposition or a CVD method, or by electroless plating.

Moreover, the shield film 9 has electric conductivity in this embodiment. Therefore, it is possible to form the shield film 9 so as to cover the entire extraction electrodes 3 and 6 including the boundary between the extraction electrode 6 and the insulating film 5. The terminal electrode 10 can be electrically connected to the extraction electrodes 3 and 6 via the shield film 9.

### Third Embodiment

FIG. 4 is a cross-sectional view schematically showing a terminal electrode in an electronic component according to a third embodiment of the present invention. As shown in the drawing, an electronic component (a chip) of this embodiment includes the shield film 9 formed as a conductive film similarly to the second embodiment. Here, the upper conductive film inclusive of the upper extraction electrode 6 is formed, and then the protective film 7 is formed on the outermost layer of the chip. Further, the shield film 9 is formed so as to cover an interface between the protective film 7 and the upper conductive film (the upper extraction electrode 6). Here, a tip end of the protective film 7 is retracted from the upper extraction electrode 6 toward the center of the chip, so that a bonding surface to the terminal electrode 10 is formed on an upper surface of the upper extraction electrode 6.

This embodiment is effective for forming a high-frequency component in particular. In the second embodiment, the shield film (the conductive film) 9 is provided so as to cover the entire upper surface of the upper extraction electrode 6 so that an electric current is concentrated on the shield film 9 along with an increase in a signal frequency due to a conductor skin effect. Here, the shield film 9 applies the material having relatively high electric resistance such as Cr, Ni or Ti from the viewpoint of the shielding property or adhesion as described above. Hence there is a possibility that a loss of the signal frequency may increase at the joint. On the contrary, according to this embodiment, the shield film 9 is formed so as to cover the upper surface side of the protective film 7. Therefore, there is no shield film on the upper surface of the upper extraction electrode 6 except the boding surface to the terminal electrode 10. This is more effective in terms of the loss of the high-frequency signals as compared to the structure of the second embodiment. Meanwhile, in order to obtain a higher shielding performance, it is also possible to form a plated film of Cu or the like on an upper surface of the shield film 9 so as to improve resistance against outside materials. Moreover, it is also possible to deal with degradation of functions attributable to a resistance loss.

Although the preferred embodiments of the present invention have been described above, it is to be noted that the present invention is not limited only to these embodiments. It is obvious to those skilled in the art that various modifications are possible without departing from the scope of the appended claims.

For example, in addition to the U-shaped electrode extending over the bottom surface, the side surface, and the top surface of the chip as described in the embodiments, it is also possible to apply an L-shaped electrode extending from the side surface to the bottom surface or from the side surface and the top surface, or an I-shaped electrode extending only on the side surface. Moreover, including the respective films constituting the terminal electrode, it is also possible to use various materials, the number of laminated films, and other forming methods for the respective films to be formed on the base substrate. For example, instead of Cu, the internal conductors (the upper conductive film and the lower conductive film) may apply other materials having low electric resistance such as Ag, Al or W.

Meanwhile, the two conductive films, the single insulating film, and the single dielectric film are illustrated in the respective embodiments. However, it is possible to provide one or any arbitrary number of these films, respectively. When the chip does not include a capacitor as a functional element unit, it is not always necessary to provide a dielectric film. Moreover, it is also possible to form one or more layers of conductive films, insulating films, and other films on a lower surface side of the base substrate. In this case, the shield film for covering an interface between an extraction electrode and an insulating film may be provided in the same way as that of the upper surface of the substrate by applying the present invention.

What is claimed is:

1. An electronic component which is formed by laminating a conductive film forming an internal conductor, and an insulating film covering the internal conductor, and which is provided with an extraction electrode extracted from the internal conductor to be exposed from the insulating film for establishing connection to another electrode, the electronic component comprising:
a shield film configured to cover an interface between the extraction electrode and the insulating film covering the internal conductor.

2. The electronic component according to claim 1,
wherein the extraction electrode is formed on an end including at least any of a upper surface, a lower surface, and a side surface of the electronic component, and
the other electrode is a terminal electrode provided on the side surface of the electronic component.

3. The electronic component according to claim 2,
wherein the extraction electrode is formed, so that the tip end of the extraction electrode is retracted inward from the side surface of the electronic component.

4. The electronic component according to claim 1,
wherein the shield film is a film having resistance to at least any of: a surface activating solution including a degreasing agent; an acidic chemical solution; and an alkaline chemical solution.

5. The electronic component according to claim 2,
wherein the shield film is a film having resistance to at least any of: a surface activating solution including a degreasing agent; an acidic chemical solution; and an alkaline chemical solution.

6. The electronic component according to claim 3,
wherein the shield film is a film having resistance to at least any of: a surface activating solution including a degreasing agent; an acidic chemical solution; and an alkaline chemical solution.

7. The electronic component according to claim 1,
wherein the shield film is a film having resistance to any of a plating solution and an etching solution.

8. The electronic component according to claim 2,
wherein the shield film is a film having resistance to any of a plating solution and an etching solution.

9. The electronic component according to claim 3,
wherein the shield film is a film having resistance to any of a plating solution and an etching solution.

10. The electronic component according to claim 1,
wherein the shield film is a film having moisture resistance, gas permeation resistance, and corrosion resistance.

11. The electronic component according to claim 2,
wherein the shield film is a film having moisture resistance, gas permeation resistance, and corrosion resistance.

12. The electronic component according to claim 3,
wherein the shield film is a film having moisture resistance, gas permeation resistance, and corrosion resistance.

13. The electronic component according to claim 1,
wherein the shield film is an inorganic film.

14. The electronic component according to claim 2,
wherein the shield film is an inorganic film.

15. The electronic component according to claim 3,
wherein the shield film is an inorganic film.

16. The electronic component according to claim 1,
wherein the shield film is an electrically conductive film.

17. The electronic component according to claim 2,
wherein the shield film is an electrically conductive film.

18. The electronic component according to claim 3,
wherein the shield film is an electrically conductive film.

19. The electronic component according to claim 16,
wherein the conductive film is a thin film formed by a vapor deposition method.

20. The electronic component according to claim 17,
wherein the conductive film is a thin film formed by a vapor deposition method.

21. The electronic component according to claim 18,
wherein the conductive film is a thin film formed by a vapor deposition method.

22. The electronic component according to claim 16,
wherein the conductive film is a film containing any of Cr, Ni, Ti, Cu, W, Ag, and Al as a main component.

23. The electronic component according to claim 19,
wherein the conductive film is a film containing any of Cr, Ni, Ti, Cu, W, Ag, and Al as a main component.

24. A method for manufacturing an electronic component, by simultaneously forming, in an aggregate state on a single base member, a plurality of electronic components each including: an internal conductor covered with an insulating film; and an extraction electrode extracted from the internal conductor to be exposed from the insulating film for establishing connection to another electrode, and then by separating the individual electronic components from one another by cutting the base member into chips, the method comprising:
a shield film forming step of providing each of the electronic components in the aggregate state on the base member with a shield film covering the interface between the extraction electrode and the insulating film.
